(19) United States
(12) Patent Application Publication
(10) Pub. No.: US 2025/0202343 A1
(43) Pub. Date: Jun. 19, 2025

(54) POWER MODULE AND STATIC POWER CONVERTER

(71) Applicant: Commissariat à l'Energie Atomique et aux Energies Alternatives, PARIS (FR)

(72) Inventor: Luis-Gabriel ALVES RODRIGUES, GRENOBLE (FR)

(21) Appl. No.: 18/971,200

(22) Filed: Dec. 6, 2024

(30) Foreign Application Priority Data
Dec. 14, 2023 (FR) 2314133

(51) Int. Cl. H02M 1/088; H02M 7/00; H02M 7/217; H02M 7/539

(52) U.S. Cl. CPC H02M 1/088; H02M 7/003; H02M 7/2173; H02M 7/539

(57) ABSTRACT

Power module (1000.1, 1000.2), comprising 2n switches (102) intended to form n switching cells between a first electrical contact (104.1, 104.2) and n second electrical contacts (106.1-106.3), n being greater than or equal to 2, each of the second contacts being coupled to two of the switches, comprising a circuit for driving the switches, and wherein: the switches are juxtaposed two by two; each of the cells is formed by two first switches coupled to different, juxtaposed second contacts, and by two second switches each coupled to one of the different second contacts; the driver circuit is configured to control the switches so that, at the switching of each of the switching cells, one of the second switches is turned off, after which one of the first switches is turned on, after the other first switch is turned off, and then the other second switch is turned on.

### FIELD

The present disclosure generally concerns the field of electric power conversion, and particularly that of static power converters and of the power modules of such converters.

### BACKGROUND

A static power converter of DC-to-AC (conversion of DC electrical energy into AC electrical energy) or AC-to-DC (conversion of AC electrical energy into DC electrical energy) type comprises switches and passive elements (capacitors, inductors, resistors). Depending on the nature of the DC and AC sources (capacitive or inductive), bidirectional voltage switches, or bidirectional current and voltage switches, are used in the converter.

Vertical or horizontal semiconductor components, for example MOSFET, IGBT, and HEMT transistors, or diodes, are generally used to form the switches of static power converters. Each bidirectional voltage switch is for example formed by a MOSFET, HEMT, or IGBT transistor coupled in series with a diode, or two MOSFET, HEMT, or IGBT transistors coupled in anti-series to each other. The metallizations, or electrical connectors, for the vertical components are present on the front and rear surfaces of the stack of materials forming these components.

In a converter of DC-to-AC current inverter type and of AC-to-DC voltage rectifier type, switches can be distributed in two groups, called “low-side” and “high-side”, according to their common connection points (called “N” or negative side when this common connection point is coupled to a negative terminal of the electric power source in the case of “low-side” switches, or “P” or positive side when this common connection point is coupled to a positive terminal of the electric power source in the case of “high-side” switches). For example, the switching cells formed by the switches of such a converter are three per group for a three-phase static power converter.

In order to impose the same operating constraints on all the switches of the converter, all the switching cells of the converter have the same parasitic elements (for example, parasitic inductors). Further, to reduce these parasitic elements, all the switches of a same group may be integrated in a single power module. The two power modules integrated in the converter, one comprising the low-side switches and the other comprising the high-side switches, are designed identically so that all the switching cells of the converter have the same parasitic elements. In another configuration, it is possible for the switches of the two high-side and low-side groups to be integrated in a single power module.

A first configuration of a power module consists in arranging each group of chips forming the components of each switch parallel to one another, and arranged side by side. For example, considering three switching cells formed according to this first configuration, with a central switch juxtaposed to two lateral switches, two of them are said to be “short” because they are formed by two switches juxtaposed to each other (one of the lateral switches and the central switch), and the third cell is said to be “long” because it is formed by two switches not juxtaposed to each other (the two lateral switches). A problem with this first configuration is that the properties of the obtained switching cells are not identical to one another, since not all the switch components are submitted to the same operating stress (electrical and/or thermal). For example, given the high switching speed of the cells, parasitic inductances generate different overvoltages between chips, which may result in aging differences between chips. This may compromise the reliability of the module. This problem is exacerbated when so-called wide bandgap power semiconductor components, comprising for example SiC or GaN, are used.

A second configuration of a power module consists in arranging the chips forming the components of each switch in a star around a central point of the module, each branch of this star being formed by one of the switches. By arranging the switches in such a way that the angles formed between two adjacent branches of the star are all equal, the properties of the obtained switching cells are effectively identical. The balancing of the stress on the chips is ensured for all the switching cells. However, this second configuration is more bulky than the first one, the substrate being in this case poorly utilized (particularly when it has a square or rectangular shape, since much of the surface area of the substrate is unused) or having an impractical form factor.

### SUMMARY

There thus exists a need to provide a power module and a static power converter which do not have one or more of the previously-described disadvantages.

An embodiment overcomes all or part of these disadvantages and provides a power module, comprising at least 2n switches intended to form n switching cells between a first electrical contact and n second electrical contacts, n being an integer greater than or equal to 2, each of the second electrical contacts being coupled to at least two of the switches, further comprising a circuit for driving the switches, and wherein:
the switches are arranged two by two, side by side;
each of the switching cells is intended to be formed by two first ones of the switches coupled to different second electrical contacts and arranged side by side, and by two second ones of the switches, each coupled to one of said different second electrical contacts;
the driver circuit is configured to control the switches so that, at the switching each of the switching cells, one of the second switches switches from the on state to the off state, after which one of the first switches switches from the off state to the on state, after which the other of the first switches passes from the on state to the off state, and then the other of the second switches switches from the off state to the on state.

According to a specific embodiment, n is an integer greater than or equal to 3.

According to a specific embodiment, two of the switches are coupled to one of the second electrical contacts, the other switches being arranged between said two of the switches.

According to a specific embodiment, for each of the switching cells, the different second electrical contacts to which are coupled the two second switches are arranged side by side.

According to a specific embodiment, the control circuit is configured in such a way that, at the switching of each of the switching cells:
after the switching from the on state to the off state of said one of the second switches, said one of the first switches switches from the off state to the on state after a first waiting period having a duration shorter than 1 μs, and/or
after the switching from the off state to the on state of one of the first switches, said other one of the first switches switches from the on state to the off state after an overlap period having a duration shorter than 1 μs, and/or
after the switching from the on state to the off state of said other one of the first switches, said other one of the second switches switches from the off state to the on state after a second waiting period having a duration shorter than 1 μs.

According to a specific embodiment, the power module comprises a stack of electrically-conductive layers electrically insulated from one another and forming the second electrical contacts.

According to a specific embodiment, the switches are bidirectional for voltage, or bidirectional for voltage and for current.

According to a specific embodiment, each switch comprises a transistor and a diode coupled in anti-series, or two transistors coupled in anti-series to each other.

According to a specific embodiment, the switches comprise power components based on wide bandgap semiconductor such as SiC and/or GaN.

There is also provided a static power converter, comprising at least one power module according to a specific embodiment.

According to a specific embodiment, the power module is arranged in a package comprising, on a surface, connection pads electrically coupled to the first and second electrical contacts and to electrodes for controlling the switches.

According to a specific embodiment, the static power converter is configured to be coupled to at least one electric power source, and each of the switches of the power module is sized to conduct a current value proportional to that of the current intended to be delivered by the electric power source.

According to a specific embodiment, each of the switches of the power module is sized to conduct a current value equal to half that of the current intended to be delivered by the electric power source.

According to a specific embodiment, the n second electrical contacts are common to the high-side switches and to the low-side switches of the static power converter.

According to a specific embodiment, the n second electrical contacts are arranged between the high-side switches and the low-side switches.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 schematically shows two power modules of an example of a static power converter according to a specific embodiment;

FIG. 2 schematically shows an example of a static power converter according to a specific embodiment;

FIG. 3 schematically shows examples of bidirectional voltage switches used in a power module according to a specific embodiment;

FIG. 4 schematically shows examples of embodiment of power semiconductor components used to form switches of a power module according to a specific embodiment;

FIG. 5 schematically shows an example of configuration and of arrangement of components within a power module according to a specific embodiment;

FIG. 6 schematically shows an example of electrically-conductive layers insulated from one another used to form the second electrical contacts of a power module according to a specific embodiment;

FIG. 7 schematically shows an example of an embodiment of an integrated power module according to a specific embodiment;

FIG. 8 schematically shows a cross-section view of an integrated power module according to a specific embodiment;

FIG. 9 schematically shows a timing diagram of examples of signals for controlling switches of one of the switching cells of a power module according to a specific embodiment.

### DETAILED DESCRIPTION OF THE PRESENT EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the forming of the different elements and circuits (switch components, driver circuit, etc.) is not detailed. Those skilled in the art will be capable of implementing in detail the various described functions based on the functional description given herein.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, “lateral”, etc., or orientation qualifiers, such as “horizontal”, “vertical”, etc., reference is made unless otherwise specified to the orientation of the drawings. However, these terms do not presume the actual position and orientation of the device in use.

Unless specified otherwise, the expressions “about”, “approximately”, “substantially”, and “in the order of” signify plus or minus 10%, preferably of plus or minus 5%.

In the examples of embodiments described hereafter, a static power converter comprises one or a plurality of power modules formed of active components, as well as passive components such as inductors, capacitors, etc. The active components of a power module correspond to switches.

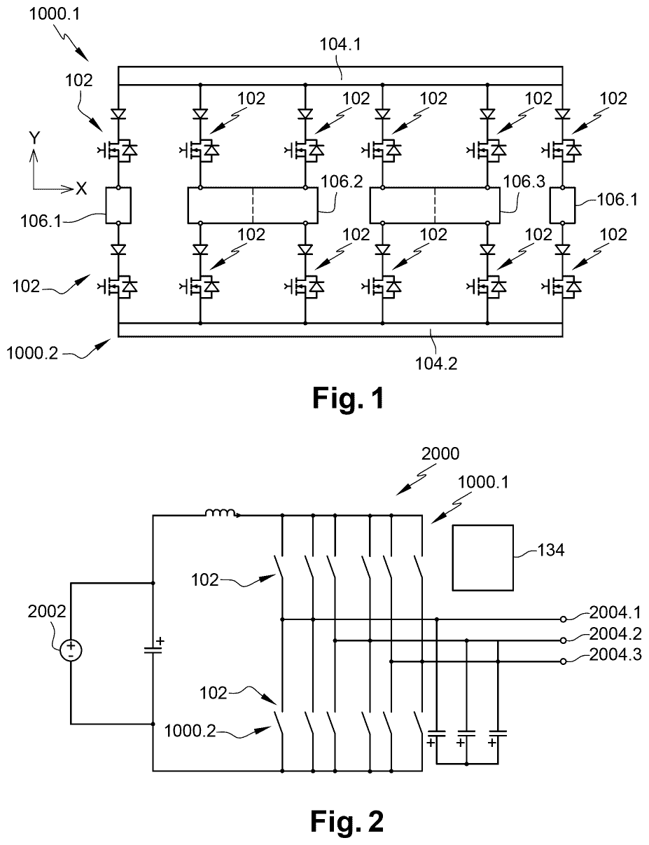

An example of power modules 1000.1, 1000.2 that may form part of a static power converter, according to a specific embodiment, is described hereafter in relation with FIG. 1. These power modules 1000.1 and 1000.2 correspond, for example, to those of the static power converter 2000 shown in FIG. 2.

In the example of FIG. 1, module 1000.1 corresponds to the so-called high-side module and module 1000.2 corresponds to the so-called low-side module of static power converter 2000.

Each module 1000.1, 1000.2 comprises at least 2n switches 102 intended to form n switching cells between a first electrical contact and n second electrical contacts, n being an integer greater than or equal to 2. In the example of FIG. 1, n=3. Such a configuration is for example adapted when converter 2000, including these modules 1000.1 and 1000.2, is configured to perform a current or voltage conversion with, on the one hand, a DC voltage, or current, intended to be obtained between the first electrical contacts of modules 1000.1, 1000.2, and, on the other hand, three-phase voltages, or currents, intended to be obtained on each of the second electrical contacts.

As an example, when n=3, converter 2000 may correspond to a current inverter and/or a three-phase voltage rectifier ensuring the conversion between a DC voltage or current source, for example a photovoltaic panel, coupled to the first electrical contacts of modules 1000.1, 1000.2, and three-phase voltages, for example intended to be injected and/or received on a grid or a rotating machine such as a motor and obtained on the second electrical contacts of modules 1000.1, 1000.2. FIG. 2 shows such a configuration of converter 2000, which forms a current inverter electrically coupled to a photovoltaic panel 2002 (symbolized in the form of a DC voltage source) and to three-phase voltage connections 2004.1-2004.3. In FIG. 2, converter 2000 also comprises passive components such as capacitors and inductors, which are not described in detail herein.

As a variant, it is possible for n to be greater than 3.

The switches 102 of each module 1000.1, 1000.2 are arranged side by side, two by two. In the example of FIG. 1, the switches 102 of each module 1000.1, 1000.2 are arranged side by side along a direction parallel to the X axis. In each module 1000.1, 1000.2, switches 102 are thus arranged parallel to one another, side by side, occupying together a rectangular or square surface area.

In the example of FIG. 1, each of the switches 102 of the first module 1000.1 comprises a first connection terminal electrically coupled to a first electrical contact 104.1. In this example, a positive terminal of an electric power source, not shown in FIG. 1, is intended to be electrically coupled to this first electrical contact 104.1. Further, in this example, each of the switches 102 of the second module 1000.2 comprises a first connection terminal electrically coupled to another first electrical contact 104.2 to which a negative terminal of the electric power source is intended to be electrically coupled.

Further, in the example of FIG. 1, each of the switches 102 of the first module 1000.1 and of the second module 1000.2 comprises a second connection terminal electrically coupled to one of n second electrical contacts, designated with references 106.1-106.3 in FIG. 1. Each of the second electrical contacts 106.1-106.3 is electrically coupled to at least two of the switches 102 of each of modules 1000.1, 1000.2. In the example of FIG. 1, each of the second electrical contacts 106.1-106.3 is electrically coupled to two of the switches 102 of each of modules 1000.1, 1000.2. In this example, the second electrical contacts 106.1-106.3 are common to modules 1000.1, 1000.2.

In the example of FIG. 1, second electrical contact 106.1 comprises two separate and spaced-apart portions which are electrically coupled to each other to form a single second electrical contact (the electrical connection between these two portions is not shown in FIG. 1). Further, each of second electrical contacts 106.2, 106.3 comprises two juxtaposed portions, electrically coupled to each other and to which two switches 102 of each of the modules 1000.1, 1000.2 are electrically coupled. In FIG. 1, the two portions of each of the second electrical contacts 106.2, 106.3 are symbolically delimited by a dotted line.

In the configuration shown in FIG. 1, for each of modules 1000.1, 1000.2, the switches 102 coupled to second electrical contacts 106.2, 106.3 are arranged between the two switches 102 coupled to second electrical contact 106.1. A possible configuration of the portions of these second electrical contacts 106.1-106.3 is a side-by-side arrangement of these different portions, for example parallel to the X axis, in the following order: first portion of contact 106.1; first portion of contact 106.2; second portion of contact 106.2; first portion of contact 106.3; second portion of contact 106.3; second portion of contact 106.1.

Other configurations of switches 102 and of the second electrical contacts 106.1-106.3 than that shown in FIG. 1 are possible. For example, it is possible for each of the second electrical contacts 106.1-106.3 to comprise two separate spaced-apart portions which are electrically coupled to each other. A possible configuration of the portions of these second electrical contacts 106.1-106.3 is a side-by-side arrangement of these different portions, for example parallel to the X axis, in the following order: first portion of contact 106.1; first portion of contact 106.2; first portion of contact 106.3; second portion of contact 106.1; second portion of contact 106.2; second portion of contact 106.3.

In each module 1000.1, 1000.2, each of the switching cells is intended to be formed by two first ones of switches 102 coupled to different second electrical contacts 106.1-106.3 arranged side by side, and by two second ones of switches 102, each coupled to one of said different second electrical contacts 106.1-106.3. In the example shown in FIG. 1, for module 1000.1:
a first switching cell is intended to switch between a first conduction path extending between first electrical contact 104.1 and second electrical contact 106.1, and a second conduction path extending between first electrical contact 104.1 and second electrical contact 106.2;
a second switching cell is intended to switch between a first conduction path extending between first electrical contact 104.1 and second electrical contact 106.2, and a second conduction path extending between first electrical contact 104.1 and second electrical contact 106.3;
a third switching cell is intended to switch between a first conduction path extending between first electrical contact 104.1 and second electrical contact 106.3, and a second conduction path extending between first electrical contact 104.1 and second electrical contact 106.1.

Similarly, for the module 1000.2 shown in FIG. 1:
a first switching cell is intended to switch between a first conduction path extending between first electrical contact 104.2 and second electrical contact 106.1, and a second conduction path extending between first electrical contact 104.2 and second electrical contact 106.2;
a second switching cell is intended to switch between a first conduction path extending between first electrical contact 104.2 and second electrical contact 106.2, and a second conduction path extending between first electrical contact 104.2 and second electrical contact 106.3;
a third switching cell is intended to switch between a first conduction path extending between first electrical contact 104.2 and second electrical contact 106.3, and a second conduction path extending between first electrical contact 104.2 and second electrical contact 106.1.

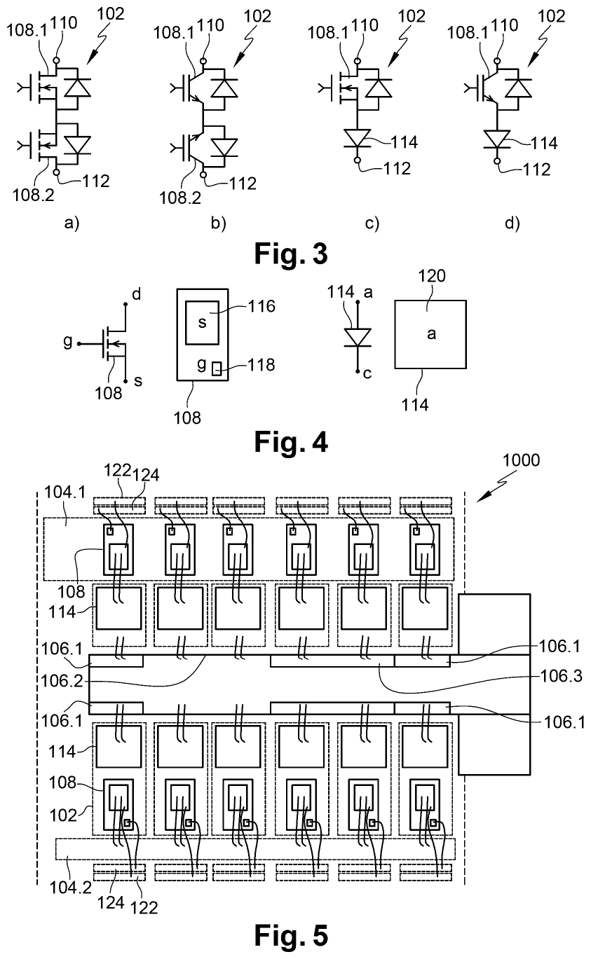

In a specific configuration, the switches 102 of modules 1000.1, 1000.2 may be bidirectional for voltage only, or bidirectional for voltage and for current. Examples of embodiment of such bidirectional switches 102 are schematically shown in FIG. 3. Such switches 102 may each be obtained by coupling two chips, each forming a one-way switch, or may each be formed on a single chip.

In example a) of FIG. 3, switch 102 comprises two transistors 108.1, 108.2 coupled in anti-series to each other. In this example, transistors 108.1, 108.2 are MOSFETs and are of type N. The drain of the first transistor 108.1 forms a first connection terminal 110 of switch 102, the drain of the second transistor 108.2 forms a second connection terminal 112 of switch 102, and the sources of transistors 108.1, 108.2 are coupled together. The shown diodes, coupled parallel to transistors 108.1, 108.2, correspond to the parasitic diodes of these transistors or to external diodes coupled in parallel with these transistors 108.1, 108.2. In this configuration, the flowing of a current from the first connection terminal 110 to the second connection terminal 112 is possible by having transistor 108.1 in the on state and transistor 108.2 in the off state (the current flowing through transistor 108.2 via its parasitic diode or the external diode coupled in parallel with transistor 108.2). The flowing of a current from the second connection terminal 112 to the first connection terminal 110 is possible with transistor 108.1 in the off state (the current flowing through transistor 108.1 via its parasitic diode or the external diode connected in parallel with transistor 108.1) and transistor 108.2 in the on state.

In example b) of FIG. 3, switch 102 comprises, as in example a), two transistors 108.1, 108.2 coupled in anti-series with each other. In this example b), transistors 108.1, 108.2 are IGBTs and are of type N. The collector of the first transistor 108.1 forms a first connection terminal 110 of switch 102, the collector of the second transistor 108.2 forms a second connection terminal 112 of switch 102, and the emitters of transistors 108.1, 108.2 are coupled to each other. The shown diodes, coupled parallel to transistors 108.1, 108.2, correspond to the parasitic diodes of these transistors or to external diodes coupled in parallel to these transistors 108.1, 108.2. The operation of such a switch is similar to that described hereabove for example a).

In example c) of FIG. 3, switch 102 comprises a transistor 108.1 coupled in series with a diode 114. In this example, transistor 108.1 is a MOSFET and is of type N. The drain of transistor 108.1 forms a first connection terminal 110 of switch 102, the cathode of diode 114 forms a second connection terminal 112 of switch 102, and the source of transistor 108.1 is coupled to the anode of diode 114. In this configuration, the flowing of a current from the first connection terminal 110 to the second connection terminal 112 is possible by having transistor 108.1 in the on state. The flowing of a current from the second connection terminal 112 to the first connection terminal 110 is not possible due to the presence of diode 114.

In example d) of FIG. 3, switch 102 is similar to that of example c), except that transistor 108.1 is an IGBT.

Other examples of switches 102 are possible: use of switches other than transistors, use of transistors other than MOSFETs and/or IGBTs, such as for example HEMT transistors, switches comprising different types of transistors, use of P-type transistor(s), etc. Further, for the previously-described examples c) and d), it is possible to interchange the components. Thus, for example c), this amounts to coupling the anode of diode 114 to the first connection terminal 110, and to coupling the source of transistor 108 to the second connection terminal 112.

In a specific configuration, the switches 102 of modules 1000.1, 1000.2 comprise vertical power components, for example based on wide bandgap semiconductor, such as SiC and/or GaN. The use of wide bandgap semiconductor-based components to form switches 102 enables to have higher switch switching speeds than with other types of components.

FIG. 4 schematically shows an example of vertical implementation of a transistor 108. In this example, transistor 108 has electrical source 116 and gate 118 contacts accessible on a first surface of the component, and an electrical drain contact (not visible in FIG. 4) accessible on a second surface, opposite to the first surface, of the component.

An example of vertical implementation of a diode 114 is also shown in FIG. 4. In this example, diode 114 has an electrical anode contact 120 accessible on a first surface of the component, and an electrical cathode contact (not visible in FIG. 4) accessible on a second surface, opposite to the first surface, of the component.

The components of switches 102 may each have a current rating, that is, a current conduction capacity, which is proportional to the semiconductor surface area used by each of these components. In a specific configuration, each of the switches 102 of modules 1000.1, 1000.2 may be sized to conduct a current value proportional to and smaller than the current intended to be delivered by a current source coupled to converter 2000, or even potentially equal to half the current intended to be delivered by this current source.

As a variant, converter 2000 may comprise more than two power modules, for example two so-called high-side modules and two so-called low-side modules.

As a variant, the high-side and low-side switches may be integrated in a single power module.

FIG. 5 schematically shows an example of configuration and of arrangement of the same switches as those previously described in relation with FIG. 1, but arranged within a same power module 1000. Further, in the example of FIG. 5, the diodes and the transistors of the switches of the high-side portion are interchanged with respect to the configuration previously described in relation with FIG. 1, that is, each correspond to the configuration of example c) of FIG. 3. This arrangement particularly has the advantage of providing a good accessibility of the transistor gate control terminals on the edges of power module 1000. However, as a variant, the switches of the high-side portion may be formed as previously described in relation with FIG. 1.

In the example of FIG. 5, the switches 102 of the low-side portion correspond to those shown for the module 1000.2 of FIG. 1. In this example, each of the switches 102 of the low-side portion is formed by a diode 114 and a MOSFET transistor 108 such that:
the anode of diode 114 is electrically coupled to one of the second electrical contacts 106.1-106.3;
the cathode of diode 114 is electrically coupled to the drain of transistor 108 (electrical connection not shown in FIG. 5);
the source of transistor 108 is electrically coupled to first electrical contact 104.2.

In the example of FIG. 5, the source and the gate of transistor 108 of each of the switches 102 of the low-side portion are also electrically coupled to other electrical contacts 122, 124, known as Kelvin contacts or sources, used to improve the transistor gate driving.

The switches 102 of the high-side portion of the module 1000 of FIG. 5 are however different from those of the module 1000.1 shown in FIG. 1. In this example, each of switches 102 is formed by a diode 114 and a MOSFET transistor 108 such that:
the cathode of diode 114 is electrically coupled to one of the second electrical contacts 106.1-106.3;
the anode of diode 114 is electrically coupled to the source of transistor 108;
the drain of transistor 108 is electrically coupled to first electrical contact 104.1.

In the example of FIG. 5, the source and the gate of the transistor 108 of each of the high-side switches 102 of module 1000 are also electrically coupled to other electrical contacts 122, 124 (Kelvin contact or source).

In a specific configuration such as that shown in FIG. 5, the second electrical contacts 106.1-106.3 are arranged between the high-side and low-side portions of power module 1000. Further, the second electrical contacts 106.1-106.3 are here formed by a stack of electrically-conductive layers, which are electrically insulated from one another. These electrically-conductive layers may be coplanar. Further, these layers may for example be formed by:
an assembly or stack of double-sided insulated substrates, for example made of DBC-type ceramic or of epoxy resin of FR4-PCB type, or
a multilayer insulated substrate, for example made of DBC-type ceramic or of epoxy resin of FR4-PCB type, or
an assembly or stack of insulated copper bars (a laminated busbar arrangement for example), or
a flexible multilayer printed circuit board.

Further, in this example, layers 126, 128, and 130 each comprise an end, respectively designated with reference 127, 129, and 131 forming electrical accesses to these layers and which are not superimposed one on top of the other when these layers are stacked one on top of the other.

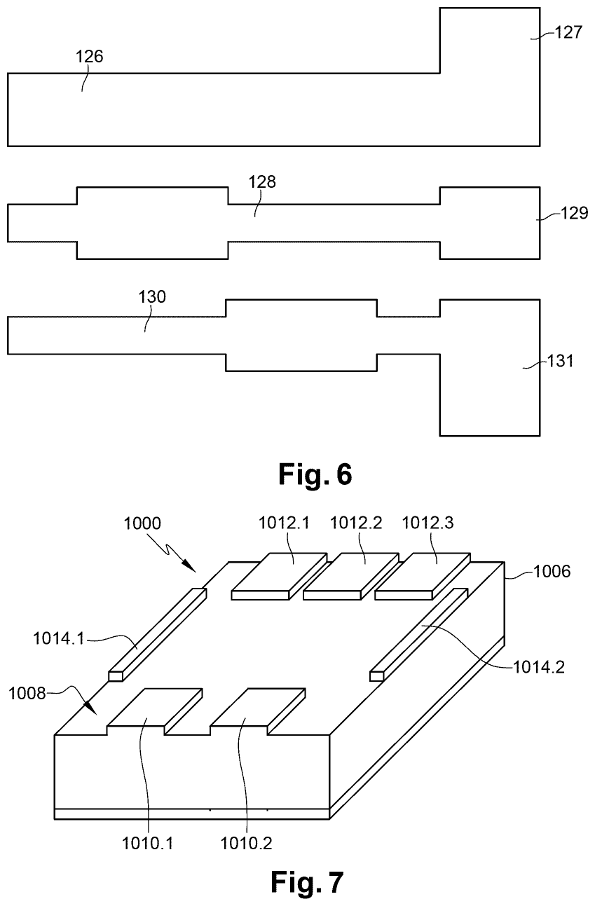

Examples of electrically-conductive layers forming the second electrical contacts 106.1-106.3 of the power module 1000 of FIG. 5 are shown in FIG. 6. Layer 126 forms second electrical contact 106.1, layer 128 forms second electrical contact 106.2, and layer 130 forms second electrical contact 106.3.

Semiconductor components 108, 114 and electrical contacts 104.1, 104.2, 106.1-106.3, 122, and 124 may be arranged on a substrate 132, not visible in FIG. 5, which is electrically insulated from the components of module 1000. Since switches 102 are arranged side by side, the substrate 132 used may have, in top view, a rectangular or square shape.

In a specific configuration, module 1000 may comprise a package 1006 having the groups of high-side and low-side switches arranged therein. Such a package 1006 may comprise, on a surface 1008, connection pads electrically coupled to the first and second electrical contacts 104.1, 104.2, 106.1-106.3 and to control electrodes of switches 102.

FIG. 7 schematically shows an example of embodiment of such a power module 1000 forming, with package 1006, an integrated power module. In this drawing, package 1006 comprises, on its upper surface 1008, two first connection pads 1010.1, 1010.2 each electrically coupled to one of first electrical contacts 104.1, 104.2, second connection pads 1012.1-1012.3 each electrically coupled to one of the second electrical contacts 106.1-106.3, third connection pads 1014.1, 1014.2 each electrically coupled to the control electrodes of switches 102.

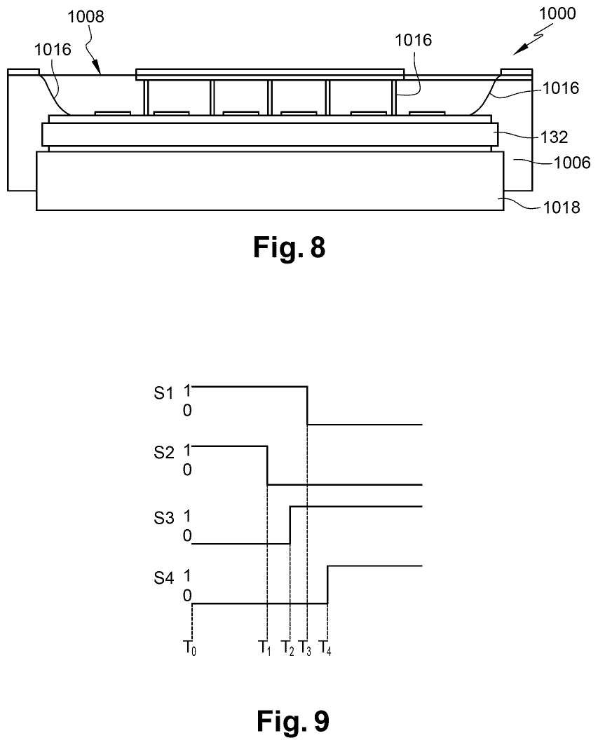

FIG. 8 schematically shows a cross-section view of an example of integrated module 1000. FIG. 8 shows, in particular, the arrangement of the different previously-described elements of power module 1000. References 1016 designate electrical connections between connection pads located on upper surface 1008 and the electrical contacts of the groups of high-side and low-side switch. Module 1000 further comprises an electrically-conductive baseplate 1018 having insulated substrate 132 attached thereto and having package 1006 attached thereto.

Each switch 102 is controlled by a driver circuit 134, shown in FIG. 2. Driver circuit 134 may be common to all the switches 102 of power module 1000.

Switches 102 and the second electrical contacts 106.1-106.3 are arranged in such a way that each of the switching cells is formed by two first ones of the switches 102 arranged side by side and coupled to different second electrical contacts 106.1-106.3, and two second ones of the switches 102 coupled to second electrical contacts 106.1-106.3 and which may not be arranged side by side. Thus, in each assembly of “high-side” or “low-side” switches, at least two switches, called first switches, of the two conduction paths for which the switching is provided by the cell are arranged side by side.

Control circuit 134 controls the switches 102 of each of the switching cells so that one of the second switches 102 switches from the on state to the off state, after which one of the first switches 102 switches from the off state to the on state, after which the other of the first switches 102 switches from the on state to the off state, and then the other of the second switches 102 switches from the off state to the on state. The on state, or conductive or saturated state, corresponds to the state in which the switch 102 conducts current, and the off state, or non-conductive state, corresponds to the state in which switch 102 does not conduct current.

FIG. 9 shows a timing diagram of such signals for controlling the switches 102 of one of the “high-side” or “low-side” groups. Taking the example of the first switching cell of the high-side group, which is intended to switch between the first conduction path from first electrical contact 104.1 to second electrical contact 106.1 and the second conduction path from first electrical contact 104.1 to second electrical contact 106.2, signals S1 to S4 are such that:
signal S1 corresponds to the signal for controlling the switch 102 electrically coupling first electrical contact 104.1 to the first portion of second electrical contact 106.1;
signal S2 corresponds to the signal for controlling the switch 102 electrically coupling first electrical contact 104.1 to the second portion of second electrical contact 106.1;
signal S3 corresponds to the signal for controlling the switch 102 electrically coupling first electrical contact 104.1 to the first portion of second electrical contact 106.2;
signal S4 corresponds to the signal for controlling the switch 102 electrically coupling first electrical contact 104.1 to the second portion of second electrical contact 106.2.

In this case, between times T0 and T1, the switches forming the first conduction path are in the on state and those forming the second conduction path are in the off state. Conduction losses are reduced in this state to a minimum. Within this time period, which is for example shorter than 1 ms, the driving algorithm implemented in driver circuit 134 can determine on which phase, or which conduction path, the next switching will take place (that corresponding to second electrical contact 106.2 in the example described herein).

At time T1, the switch 102 of the first conduction path, which is physically distant from those of the second conduction path (that coupling first electrical contact 104.1 to the second portion of second electrical contact 106.1), is turned off (corresponding to the passage from state 1 to state 0 of the signal S2 on the timing diagram of FIG. 9). During the period between times T1 and T2, for example called first waiting period, or first dead time, having a duration for example shorter than 1 μs, all the current injected into first electrical contact 104.1 is routed to the only on switch 102 of the first conduction path (that coupling first electrical contact 104.1 to the first portion of second electrical contact 106.1). Conduction losses are momentarily increased during this period.

At time T2, the switch 102 of the second conduction path which is juxtaposed to that of the first conduction path, that is, the switch coupling first electrical contact 104.1 to the first portion of second electrical contact 106.2, is turned on (corresponding to the switching from state 0 to state 1 of signal S3). The period between times T2 and T3, called overlap period, is for example shorter than 1 μs, and is used to form a path for the current injected into first electrical contact 104.1 during the switching between switches from one phase to another or from one conduction path to another. As during the period between times T1 and T2, conduction losses remain momentarily increased.

At time T3, the switch having remained up to now in the on state of the first conduction path is turned off (corresponding to the switching from state 1 to state 0 of signal S1). During the period between times T3 and T4, for example called second waiting period, or second dead time, having a duration for example shorter than 1 μs, all the current injected into first electrical contact 104.1 is routed to the only on switch 102 of the second conduction path (that coupling first electrical contact 104.1 to the first portion of second electrical contact 106.2). Conduction losses are momentarily increased during this period.

At time T4, the switch of the second conduction path (that coupling first electrical contact 104.1 to the first portion of second electrical contact 106.2) is turned on (corresponding to the switching from state 0 to state 1 of signal S4), completing the switching from the first conduction path to the second conduction path by the first switching cell.

The above description of the switching performed for the first switching cell in the group of high-side switches also applies to the switching performed for the other switching cells of the group of high-side switches, as well as for the switching cells of the group of low-side switches.

Thus, the optimizing of converter losses may be achieved by varying the duration of the above-described dead times, and/or by varying the allocation of these dead times all throughout the period between times T1 and T4.

Generally, the static converter based on power module 1000 may be of DC-to-AC type, such as a current source inverter (CSI) or a boost-type inverter (BTI), or of AC-to-DC type, such as a buck-type rectifier (BTR). The converter implemented using power module 1000 may be a three-phase static power converter used, for example, in a power grid or in a rotating machine.

In all the examples of embodiment, the described power modules provide a specific arrangement of the bare semiconductor dies forming the components of switches 102, for example on an insulated substrate (for example of any nature), jointly with a specific drive mode provided by the switch driver circuit. The provided modules may in particular enable to improve:
the use of the insulated substrate thanks to a compact arrangement of the switches, which are arranged side by side in a delimited space of rectangular or square shape (as opposed to a star arrangement of the switches), enabling to have a form factor of the space used by the switches which is decreased and well utilized;
the electrical and thermal performance of the modules due to the fact that the arrangement and the driving of the switches enable to form switching cells having identical properties with respect to one another;
the reliability of the modules due to the fact that all components are submitted to the same operating stress.

In all the examples of embodiment, the components of the switches of the power module(s) may operate in switching mode (off or on state, or saturated or non-conductive state) with a high switching frequency, for example in the order of some hundred kHz.

Various embodiments and variants have been described. Those skilled in the art will understand that certain features of these various embodiments and variants could be combined, and other variants will become apparent to those skilled in the art.

Finally, the practical implementation of the described embodiments and variants is within the abilities of those skilled in the art, based on the functional indications given hereabove.

1. Power module, comprising at least 2n switches intended to form n switching cells between a first electrical contact and n second electrical contacts, n being an integer greater than or equal to 2, each of the second electrical contacts being coupled to at least two of the switches, further comprising a circuit for driving said switches, and wherein:
the switches are arranged two by two, side by side;
each of the switching cells is intended to be formed by two first ones of the switches coupled to different second electrical contacts arranged side by side, and by two second ones of the switches, each coupled to one of said different second electrical contacts;
the driver circuit is configured to control the switches so that, at the switching of each of the switching cells, one of the second switches switches from the on state to the off state, after which one of the first switches switches from the off state to the on state, after which the other of the first switches switches from the on state to the off state, and then the other of the second switches switches from the off state to the on state.

2. Power module according to claim 1, wherein n is an integer greater than or equal to 3.

3. Power module according to claim 2, wherein two of the switches are coupled to one of the second electrical contacts, the other switches being arranged between said two of the switches.

4. Power module according to claim 2, wherein, for each of the switching cells, the different second electrical contacts to which the two second switches are coupled are arranged side by side.

5. Power module according to claim 1, wherein the driver circuit is configured so that, at the switching of each of the switching cells:
after the switching from the on state to the off state of said one of the second switches, said one of the first switches switches from the off state to the on state after a first waiting period having a duration shorter than 1 μs, or
after the switching from the off state to the on state of said one of the first switches, said other one of the first switches switches from the on state to the off state after an overlap period having a duration shorter than 1 μs, or
after the switching from the on state to the off state of said other one of the first switches, said other one of the second switches switches from the off state to the on state after a second waiting period, having a duration shorter than 1 μs.

6. Power module according to claim 1, comprising a stack of electrically-conductive layers electrically insulated from one another and forming the second electrical contacts.

7. Power module according to claim 1, wherein the switches are bidirectional for voltage, or bidirectional for voltage and for current.

8. Power module according to claim 7, wherein each switch comprises a transistor and a diode coupled in anti-series, or two transistors coupled in anti-series to each other.

9. Power module according to claim 1, wherein the switches comprise power components based on wide bandgap semiconductor such as at least one of SiC and GaN.

10. Static power converter, comprising at least one power module according to claim 1.

11. Static power converter according to claim 10, wherein the power module is arranged in a package comprising, on a surface, connection pads electrically coupled to the first and second electrical contacts and to electrodes for controlling the switches.

12. Static power converter according to claim 10, configured to be coupled to at least one electric power source, and wherein each of the switches of the power module is sized to conduct a current value proportional to that of the current intended to be delivered by the electric power source.

13. Static power converter according to claim 12, wherein each of the switches of the power module is sized to conduct a current value equal to half that of the current intended to be delivered by the electric power source.

14. Static power converter according to claim 10, wherein the n second electrical contacts are common to the high-side switches and to the low-side switches of the static power converter.

15. Static power converter according to claim 10, wherein the n second electrical contacts are arranged between the high-side switches and the low-side switches.
